(19) United States
(12) Patent Application Publication
(10) Pub. No.: US 2021/0288358 A1
(43) Pub. Date: Sep. 16, 2021

(54) CIRCUIT SYSTEM FOR A BATTERY SYSTEM

(71) Applicant: Robert Bosch GmbH, Stuttgart (DE)

(72) Inventors: Walter Von Emden, Eningen Unter Achalm (DE); Joachim Joos, Gerlingen (DE); Johannes Grabowski, Stuttgart (DE)

(21) Appl. No.: 17/260,089

(22) PCT Filed: Jul. 15, 2019
(86) PCT No.: PCT/EP2019/068996

§ 371 Date: Jan. 13, 2021

(30) Foreign Application Priority Data
Jul. 17, 2018 (DE) 10 2018 211 834.5

(51) Int. Cl. H01M 10/48; H01M 10/42; H02J 7/00; G01R 31/396; H03K 17/0812

(52) U.S. Cl. CPC H01M 10/482; H01M 10/4257; H01M 10/486; H01M 2010/4271; G01R 31/396; H03K 17/08122; H02J 7/0016

(57) ABSTRACT

A circuit system for a rechargeable battery system. The circuit system includes at least one actuator that is assigned to an individual cell of the battery system in order to switch a discharge of the cell. At least one sensor system that is assigned to the individual cell in order to monitor the cell and in order to control the actuator, as a function of the monitoring, to bring about a discharge in the case of an error state.

### FIELD

The present invention relates to a circuit system for a rechargeable battery system.

### BACKGROUND INFORMATION

Conventionally, battery systems, preferably accumulators and/or high-voltage batteries, for example for electric vehicles, can be formed from a battery pack (array) having a plurality of battery cells.

PCT Application No. WO 2010/118 310 A2 describes, for example, battery systems in which a bypass mechanism is provided for the reconfiguration of the battery system.

European Patent Application No. EP 1 289 096 A2 describes a battery system in which diodes are used to prevent a discharge of the battery cells.

PCT Application No. WO 2016/012247 describes a modular energy storage direct converter system.

It has turned out that damage of individual cells in the vicinity of a defect can cause the cell to discharge, thus bringing about heating at the location of this defect. This may also have effects on cells neighboring this cell, so that these cells also discharge, causing heating.

In order to avoid a critical state in such a case of error, technically complicated and/or costly solutions have been used for ensuring cooling.

### SUMMARY

In accordance with the present invention, a circuit system, and a method are provided. Features and details of the present invention result from the description herein, and the figures. Features and details described in connection with the circuit system according to the present invention of course also hold in connection with the method according to the present invention, and vice versa in each case, so that with regard to the disclosure of the individual aspects of the present invention mutual reference is, or can, always also be made.

In accordance with an example embodiment of the present invention, a circuit system is provided for a rechargeable battery system, preferably a battery system of a vehicle or of a mobile radiotelephone device.

The battery system can in particular be designed as a rechargeable high-voltage battery. Advantageously, the battery system has a plurality of cells (battery cells), and in this way forms a battery pack. The cells are realized in particular as 3.7 volt cells. In addition, a further subdivision of the battery into modules, each having for example 12-16 cells, can also take place. It is possible for the entire battery pack to provide an overall voltage of approximately 400 volts. For example, the overall voltage can be 200-600 volts.

The vehicle is designed for example as a passenger motor vehicle and/or as a heavy goods vehicle and/or as an electric vehicle.

In addition, it can be a hybrid vehicle or a purely electric vehicle that is propelled exclusively electrically. The mobile radiotelephone device is realized for example as a smartphone or the like.

In the circuit system according to an example embodiment of the present invention, it can be provided that the following (for example electronic) components are used:
at least one actuator that is assigned to an individual cell of the battery system in order to switch a discharging of the cell, in particular via the cell's inherent resistance,
at least one sensor system that is assigned to the individual cell in order to monitor the cell, and preferably, as a function of the monitoring, to control the actuator to bring about a discharge when there is an error state (in particular a case of error).

This has the advantage that in case of error (given the presence or occurrence of an error state), an active draining and/or deactivation of the cell, as a damaged cell, is enabled by the sensor system and/or by the actuator. Here, the discharge can take place for example via an electrical internal resistance (inherent resistance) of the cell. This may indeed also cause heating of the cell, but this is largely homogenous and no longer localized at a defect (in the area of the cell of the battery system). In order to achieve increased robustness, if appropriate each cell of the battery system can be equipped with its own diagnostic sensor (i.e., the sensor system) as well as its own actuator (e.g., one or more electronic switches).

Advantageously, the sensor system can include at least one sensor for acquiring an electrical cell voltage and/or an electrical current and/or a temperature of the cell and/or a pressure in the cell. The actuator can have for example an electrical switch that is designed to short-circuit the cell assigned to the actuator.

In addition, it is advantageous if each cell of the battery system has at least one assigned actuator and/or at least one assigned sensor system in order to monitor the respective cell, and/or to control, as a function of the monitoring, the actuator so as to bring about a discharge when there is an error state.

For example, it can be provided that the sensor system of a cell is designed to immediately control the actuator of this cell. In particular, the sensor system can be electrically connected directly to the actuator in order to switch the actuator. The actuator has for example at least one electrical switch, such as a MOSFET (metal oxide semiconductor field-effect transistor).

Advantageously, the sensor system is connected to a control input of the electrical switch in order to bring it from an open state into a closed state (or vice versa). This makes it possible to ensure a particularly fast reaction time.

Advantageously, the actuator assigned to the individual cell can be designed exclusively for the discharge of this individual cell. Alternatively or in addition, the sensor system assigned to the individual cell can be designed exclusively for monitoring this individual cell and/or exclusively for controlling the actuator assigned to this individual cell. In this way, a fast discharge of this individual cell in case of error is possible without having to make a detour via an additional device (such as a central battery management system or a control device of the vehicle or the like).

In a further possibility, it can be provided that the sensor system is designed to monitor an electrical voltage and an electrical current, and preferably also to acquire a temperature and/or a pressure in the individual cell, and preferably to compare it with a specification, in order to detect the error state in the cell through this monitoring and/or on the basis of the comparison. The specification can be stored in non-volatile fashion, for example in a data memory of the sensor system. This makes it possible to reliably detect a critical state (i.e., the error state). Optionally, it can be possible for the sensor system to have an integrated circuit, preferably an ASIC (application-specific integrated circuit), in order to provide the monitoring and/or controlling. In this way, a highly integrated and intelligent electronics system, immediately assigned to the cell, can be used to provide the monitoring and/or controlling.

In addition, it is optionally provided that the sensor system is part of a decentralized battery management system, preferably being designed as a decentralized battery management unit, in order to provide the monitoring and/or the controlling independently of a central battery management system and/or at least one further decentralized battery management unit of at least one further cell of the battery system. For example, the decentralized battery management system can have a plurality of battery management units that are assigned in decentralized fashion to individual cells. This enables a particularly fast controlling in case of error.

It can be advantageous if, in the context of the present invention, the actuator is realized as a power switch, preferably a field-effect transistor, and is in particular connected parallel to the cell, in order to short-circuit the cell for discharge via an inherent resistance (in particular internal resistance) of the cell. When this happens the cell may indeed likewise be heated, but largely homogenously, so that excess heating no longer occurs.

A method for safety discharge of individual cells of a rechargeable battery system is also provided in accordance with the present invention.

In accordance with an example embodiment of the present invention, it is provided that the following steps are carried out, preferably in succession or in any desired sequence; individual steps may if appropriate also be carried out repeatedly:
monitoring of an individual cell by a sensor system that is assigned (in particular only) to the individual cell, at least one cell voltage being monitored,
detection of an error state at least on the basis of the monitoring, preferably of a temporal curve of the cell voltage,
controlling an actuator as a function of the detection in order to discharge the cell in the error state.

As a result, the method according to the example embodiment of the present invention confers the same advantages as described above in detail with reference to a circuit system according to the present invention. In addition, the method can be suitable for operating a circuit system according to the present invention. Thus, for example the sensor system and the actuator can be realized and/or connected to the cell according to a circuit system according to the present invention.

Preferably, the detection and/or each of the above-named steps take place through the sensor system of the cell.

Advantageously, in order to ascertain the temporal curve of the cell voltage during the monitoring, a voltage value at the cell is repeatedly ascertained, this value being specific for a cell voltage of the individual cell. The voltage values ascertained in this way can be for example intermediately stored in order to evaluate the curve. The intermediate storage and/or evaluation can be done for example by the sensor system. Preferably, the error state is detected when, through the evaluation, an excessive decrease in the voltage of the cell is recognized. The decrease is recognized for example by falling below a specified negative gradient, such as −0.5 volts per μs, as threshold value.

Optionally, it can be provided that a short-circuiting of the cell is initiated as a function of the monitoring during the detection of the error state. This short-circuiting can take place in particular in a controlled fashion in order to avoid excessive heating.

Preferably, in the context of the present invention it can be provided that, as a function of the monitoring, in the detection of the error state at least one further actuator is controlled so as to discharge at least one cell adjacent to the cell (i.e., the damaged cell), preferably through a central battery management system, preferably independently of a further monitoring of the adjacent cell by a further sensor system, the adjacent cell(s) preferably being those that have a mechanical point of contact to the damaged cell. In this way, the safety can be further increased, and for example a fixed number of adjacent cells can also be discharged automatically upon detection of the error state. The adjacent cells are for example those cells that are spatially closest to the damaged battery cell in the battery system.

In addition, it is advantageous if the controlling includes a repeated, preferably pulsed, switching of the actuator, in order to limit a discharge current of the cell. In this way, an excessive development of heat can be avoided.

Further advantages, features, and details of the present invention result from the description below, in which exemplary embodiments of the present invention are described in detail with reference to the figures. Here, the features mentioned in the description may each be essential to the present invention, individually or in any combination.

### BRIEF DESCRIPTION OF THE DRAWINGS

FIG. 1 shows a schematic representation of a battery system, in accordance with an example embodiment of the present invention.

FIG. 2 shows a further schematic representation of a battery system, in accordance with an example embodiment of the present invention.

FIG. 3 shows a schematic representation of a circuit system according to an example embodiment of the present invention.

FIG. 4 shows a further schematic representation of a circuit system according to an example embodiment of the present invention,

FIG. 5 shows a schematic representation of a curve of a voltage value measured at the individual cell, in accordance with an example embodiment of the present invention.

FIG. 6 shows a schematic representation of a cell, in accordance with an example embodiment of the present invention.

### DETAILED DESCRIPTION OF EXAMPLE EMBODIMENTS

In the Figures, identical reference characters are used for the same technical features in the various exemplary embodiments.

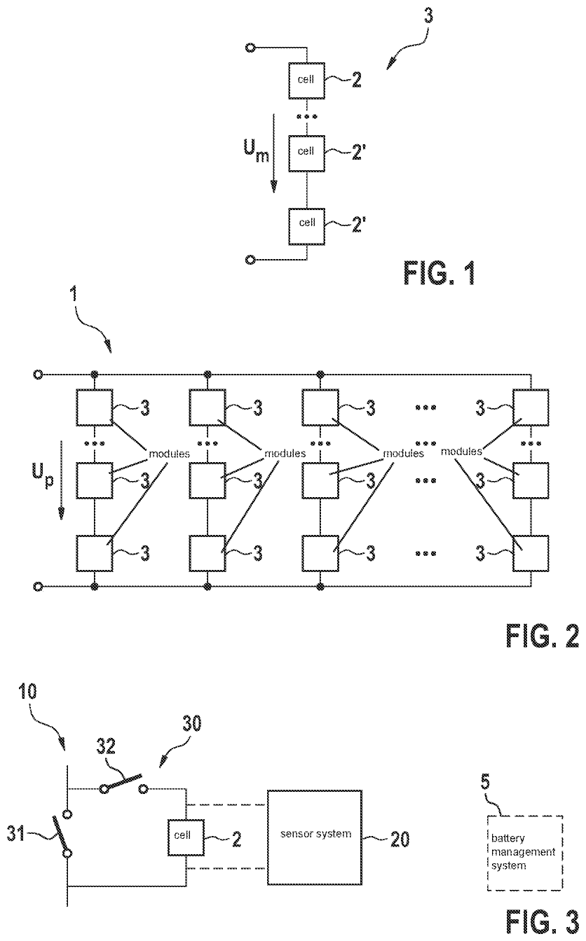

In FIG. 1, a module 3 of a battery system 1 is shown schematically. For better understanding, in addition a module voltage Um is shown. An individual module 3 of battery system 1 has for example a plurality of cells 2, 2′.

In addition, a plurality of modules 3 can be connected together in a battery system 1, in particular in a high-voltage battery for a vehicle.

This is shown in FIG. 2. The wiring of the modules 3 has the effect that a higher overall voltage Up of the battery pack as a whole can be provided.

FIG. 3 schematically shows a circuit system 10 according to the present invention for a rechargeable battery system 1. Here circuit system 10 can have at least one actuator 30 to which an individual cell 2 of battery system 1 is assigned. This actuator 30 has for example at least one electronic switch 31, 32, in order to switch a discharge of cell 2. Shown as examples are a first electronic switch 31 and second electronic switch 32, which are both connected to the individual cell 2. In the normal state, i.e., during error-free operation of battery system 1, second electronic switch 32 is closed, and first electronic switch 31 is open.

In addition, a sensor system 20 is provided that is assigned to individual cell 2 in order to monitor cell 2, and in order to control, as a function of this monitoring, actuator 30 for discharging when there is an error state F. For the detection of the error state via the monitoring, for example a voltage at cell 2 is measured by sensor system 20. In order to bring about the discharge, in error state F for example first electronic switch 31 can be closed and second electronic switch 32 can remain closed, so that the relevant cell 2 can discharge itself via its inherent resistance. In addition, through the closing of first electronic switch 31, the current of the other cells 2′ of the module can be redirected. This procedure may indeed cause a heating of cell 2, but not as localized as at a defect. The defect is for example damage to cell 2 that causes error state F.

In addition, when error state F is detected, possibly by sensor system 20, a battery management system 5 can be informed. For this purpose, for example a data line can be provided between sensor system 20 and an optional (central) battery management system 5. Equally, this data line and/or a communication between sensor system 20 and battery management system 5 may not be necessary for the controlling of actuator 30 by sensor system 20, so that the discharge in the case of error state F can also take place independently of the (central) battery management system 5.

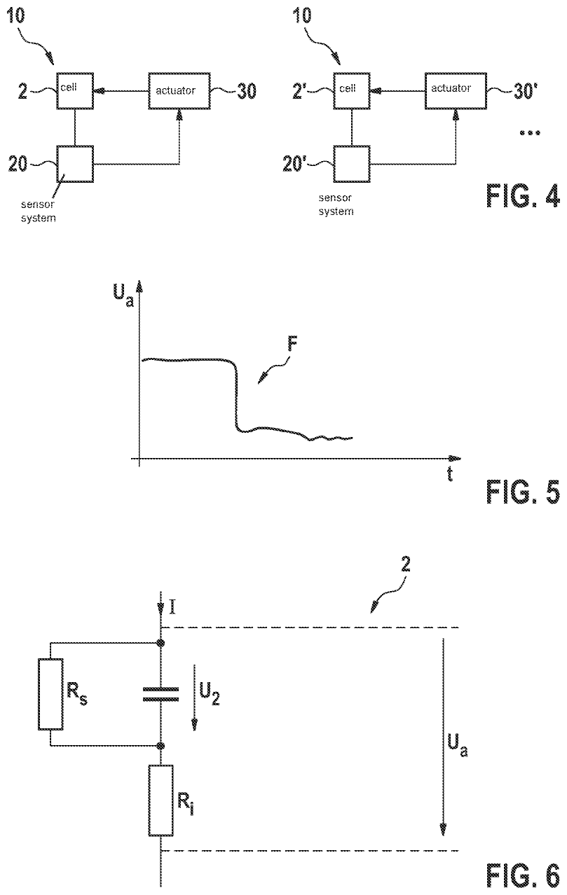

According to FIG. 4, further cells, or all further cells, 2′ of battery system 1 can each have an assigned additional sensor system 20′ and/or an assigned additional actuator 30′ and/or a circuit system 10. In this way, it is possible to detect error state F in the further cells 2′ as well, and if appropriate for a discharge to take place automatically. It is also possible for adjacent cells 2′ of a damaged cell 2 to likewise be discharged.

In addition, it is possible for a temperature at cell 2 to also be monitored by sensor system 20. For example, the discharging and/or the short-circuit can be terminated by actuator 30 if the temperature moves into a critical range.

It is also possible for the maximum discharge current to be controlled by a pulsing (repeated switching on and off, or closing and opening) of second electronic switch 32. This can in particular also be carried out by sensor system 20.

It is also possible for sensor system 20 to carry out the monitoring and/or controlling independently, and/or autarkically, from further electronic devices of the battery system and/or from central battery management system 5.

As is shown in FIG. 5, sensor system 20 can acquire, for example at regular temporal intervals, a measurement voltage Ua at cell 2 that is specific and/or is a function of a cell voltage Uz. On the basis of a rapid decrease of this voltage Ua, the occurrence of error state F can be detected. For this purpose, there takes place for example an evaluation of a curve of this voltage Ua over time t.

FIG. 6 schematically shows an equivalent circuit diagram of cell 2 (or also of further cells 2′). It can be seen that a current flow I of the cell can be influenced by a transition resistance Rs and by an inherent resistance Ri. Transition resistance Rs is for example the resistance that arises at a defect in the error state. Through a short-circuit deliberately brought about by sensor system 20 (e.g., by controlling actuator 30 and/or closing second electronic switch 32 according to FIG. 3), current I can then further be conducted only in part via Rs and can be dissipated mainly via Ri (low-ohmic contact).

The discharging according to circuit system 10 according to the present invention, and/or according to a method according to the present invention, can for example be controlled by battery management system 5 in such a way that a discharge takes place to a charge state of 60% or less, e.g., 30% (depending on the cell used), in the battery system and/or the short-circuited cells 2, 2′.

The above explanation of the specific embodiments describes the present invention exclusively in relation to examples. Of course, individual features of the specific embodiments can be freely combined with one another, to the extent that this makes sense technically, without departing from the scope of the present invention.

1-10. (canceled)

11. A circuit system for a rechargeable battery system, comprising:
at least one actuator assigned to an individual cell of the battery system and configured to switch a discharge of the cell; and
at least one sensor system assigned to the individual cell and configured to monitor the cell and to control the actuator as a function of the monitoring, to bring about a discharge of the cell in case of an error state.

12. The circuit system as recited in claim 11, wherein the sensor system is configured to directly control the actuator.

13. The circuit system as recited in claim 11, wherein the sensor system is configured to monitor an electrical voltage and/or an electrical current in the individual cell, and to compare the electrical voltage and/or electrical current with a specification to detect, through the monitoring, the error state of the cell.

14. The circuit system as recited in claim 13, wherein the sensor system is configured to acquire a temperature and/or pressure in the individual cell.

15. The circuit system as recited in claim 11, wherein the sensor system includes an integrated circuit configured to provide the monitoring and/or the controlling.

16. The circuit system as recited in claim 15, wherein the integrated circuit is an ASIC.

17. The circuit system as recited in claim 11, wherein the sensor system is part of a decentralized battery management system to provide the monitoring and/or controlling independently of a central battery management system and/or at least one further battery management unit of at least one further cell of the battery system.

18. The circuit system as recited in claim 17, wherein the sensor system is a decentralized battery management unit.

19. The circuit system as recited in claim 11, wherein the actuator is a power switch and is connected parallel to the cell to short-circuit the cell for discharging via an inherent resistance of the cell.

20. The circuit system as recited in claim 19, wherein the power switch is a field-effect transistor.

21. A method for safety discharge of individual cells of a rechargeable battery system, the method comprising the following steps:
monitoring an individual cell by a sensor system that is assigned to the individual cell, the monitoring including monitoring at least a cell voltage of the cell;
detecting an error state based on the monitoring; and
controlling an actuator as a function of the detection to discharge the cell in the error state.

22. The method as recited in claim 21, wherein, as a function of the monitoring, upon detection of the error state, a short-circuiting of the cell is initiated.

23. The method as recited in claim 21, wherein, as a function of the monitoring, upon detection of the error state, at least one further actuator is controlled for discharging at least one cell adjacent to the cell.

24. The method as recited in claim 23, wherein, as a function of the monitoring, upon detection of the error state, at least one further actuator is controlled for discharging at least one cell adjacent to the cell, independently of a further monitoring of the adjacent cell by a further sensor system.

25. The method as recited in claim 21, wherein the controlling includes a repeated, pulsed, switching of the actuator to limit a discharge current of the cell.
